(19) United States
(12) Patent Application Publication
(10) Pub. No.: US 2021/0313772 A1
(43) Pub. Date: Oct. 7, 2021

(54) OPTICAL SEMICONDUCTOR DEVICE AND METHOD FOR MANUFACTURING OPTICAL SEMICONDUCTOR DEVICE

(71) Applicant: Mitsubishi Electric Corporation, Tokyo (JP)

(72) Inventors: Hiroyuki KAWAHARA, Tokyo (JP); Eiji NAKAI, Tokyo (JP)

(73) Assignee: Mitsubishi Electric Corporation, Tokyo (JP)

(21) Appl. No.: 17/264,969

(22) PCT Filed: Nov. 1, 2018
(86) PCT No.: PCT/JP2018/040645

§ 371 Date: Feb. 1, 2021

(51) Int. Cl. H01S 5/22; H01S 5/223; H01S 5/227

(52) U.S. Cl. CPC H01S 5/221; H01S 5/227; H01S 5/2231

(57) ABSTRACT

An optical semiconductor device is provided with: a mesa in which a first conductivity type cladding layer, an active layer, and a second conductivity type first cladding layer having a second conductivity type are sequentially laminated on a surface of a first conductivity type substrate; a buried layer that buries both sides of the mesa with a top of the mesa being exposed; and a second conductivity type second cladding layer that buries the buried layer and the top of the mesa exposed from the buried layer, wherein the buried layer includes a layer doped with a semi-insulating material, and a boundary between the second conductivity type first cladding layer and the buried layer is inclined so that a width of the second conductivity-type first cladding layer becomes narrower toward the top of the mesa.

### TECHNICAL FIELD

The present application relates to an optical semiconductor device and a method for manufacturing the same.

### BACKGROUND ART

In an optical semiconductor device represented by a semiconductor laser, a structure (so-called buried-type laser) in which sides of an active layer are buried with a semiconductor material is often used for the purpose of current constriction to the active layer and heat dissipation from the active layer. In an InP-based buried-type laser used for optical communication applications, a combination of an n-type InP substrate and an InP buried layer doped with a semi-insulating material such as Fe is used to reduce capacitance for high speed modulation. Since Fe acts as an electron trap in InP and does not have a trapping effect on holes, a structure in which an n-type InP layer is disposed in a portion in contact with the p-type cladding layer above the buried layer is generally used. With respect to the structure described above, in order to further improve current injection efficiency, Patent Document 1 proposes a structure in which constriction is made above the active layer by an n-type InP layer to further strengthen the current constriction to the active layer.

### CITATION LIST

### Patent Document

Patent Document 1: JP 2011-249766A

### SUMMARY OF THE INVENTION

### Problems to be Solved by the Invention

However, in the structure described in Patent Document 1, it is necessary to perform mesa formation and burying growth several times for the constriction by the buried layer, and there is a problem in that the manufacturing cost increases. In addition, since the degree of difficulty of pattern alignment several times at the time of forming the mesa or the degree of difficulty of pattern formation itself is high, stable yield cannot be expected.

It is an object of the present application to provide a technique for solving the above problems, to simply and stably obtain a current constriction structure above the active layer by one mesa formation and one burying growth, and to provide a manufacturing method suitable for the structure.

### Means for Solving Problems

An optical semiconductor device disclosed in the present application includes:

a mesa in which a first conductivity type cladding layer having a first conductivity type, an active layer, and a second conductivity type first cladding layer having a second conductivity type being a conductivity type opposite to the first conductivity type are sequentially laminated on a surface of a first conductivity type substrate having the first conductivity type;

a buried layer that buries both sides of the mesa with a top of the mesa being exposed; and

a second conductivity type second cladding layer having the second conductivity type that buries the buried layer and the top of the mesa exposed from the buried layer, wherein the buried layer includes a layer doped with a semi-insulating material; and a boundary between the second conductivity type first cladding layer and the buried layer is inclined so that a width of the second conductivity type first cladding layer becomes narrower toward the top of the mesa.

A manufacturing method for an optical semiconductor device disclosed in the present application includes the steps of:

forming a laminated structure by sequentially laminating a first conductivity type cladding layer having a first conductivity type, an active layer, and a second conductivity type first cladding layer having a second conductivity type being a conductivity type opposite to the first conductivity type on the surface of a first conductivity type substrate having a first conductivity type in an MOCVD furnace;

forming a mesa by forming a mask having a predetermined width on a surface of the laminated structure and by etching both sides of the laminated structure to a position closer to the first conductivity type substrate than the active layer by dry etching;

forming side faces of the second conductivity type first cladding layer to be inclined faces by etching the formed mesa with a halogen-based gas flowing into the MOCVD furnace while the mask is left;

burying both sides of the mesa formed to be the inclined faces in the side faces of the second conductivity type first cladding layer with a buried layer including a layer doped with a semi-insulating material; and forming a second conductivity type second cladding layer to cover the buried layer and the second conductivity type first cladding layer that is exposed at a top of the mesa after removing the mask.

### Effect of the Invention

According to the optical semiconductor device and the manufacturing method for the optical semiconductor device disclosed in the present application, it is possible to provide an optical semiconductor device and a manufacturing method for the optical semiconductor device capable of simply and stably obtaining the current constriction structure above the active layer.

### BRIEF DESCRIPTION OF DRAWINGS

FIG. 1 is a cross-sectional view illustrating a schematic configuration of an optical semiconductor device according to Embodiment 1.

FIG. 2A is a first diagram showing a step of a manufacturing method for the optical semiconductor device according to Embodiment 1.

FIG. 2B is a second diagram showing a step of the manufacturing method for the optical semiconductor device according to Embodiment 1.

FIG. 2C is a third diagram showing a step of the manufacturing method for the optical semiconductor device according to Embodiment 1.

FIG. 2D is a fourth diagram showing a step of the manufacturing method for the optical semiconductor device according to Embodiment 1.

FIG. 2E is a fifth diagram showing a step of the manufacturing method for the optical semiconductor device according to Embodiment 1.

FIG. 2F is a sixth diagram showing a step of the manufacturing method for the optical semiconductor device according to Embodiment 1.

FIG. 3 is a cross-sectional view illustrating a schematic configuration of an optical semiconductor device according to Embodiment 2.

FIG. 4 is a cross-sectional view illustrating a schematic configuration of an optical semiconductor device according to Embodiment 3.

FIG. 5 is a cross-sectional view showing a schematic configuration of an optical semiconductor device of a comparative example.

### MODES FOR CARRYING OUT THE INVENTION

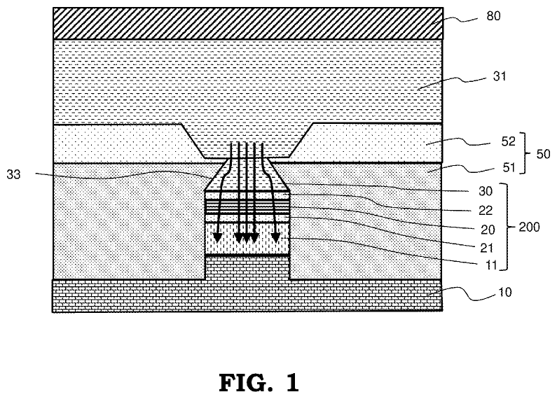

FIG. 1 is a cross-sectional view illustrating a schematic configuration of an optical semiconductor device according to Embodiment 1. Here, an example of a semiconductor laser having an AlGaInAs active layer on an n-type InP substrate 10 is shown as the optical semiconductor device. On the n-type InP substrate 10, a mesa 200 of a laminated body in a stripe shape is formed in which an n-type InP cladding layer 11 (thickness: 1.0 μm, doping concentration: 1.0×10¹⁸ cm⁻³), an undoped AlGaInAs active layer 20 (thickness: 0.3 μm) sandwiched between an AlGaInAs upper optical confinement layer 22 and an AlGaInAs lower optical confinement layer 21, and a p-type InP first cladding layer 30 (thickness: 0.3 μm, doping concentration: 1.0×10¹⁸ cm⁻³) are laminated. Both sides of the mesa 200 are buried with a buried layer 50. The buried layer 50 is formed of an Fe-doped InP buried layer 51 being a semi-insulating material (film thickness: 1.8 μm, doping concentration: 5.0×10¹⁶ cm⁻³) and an n-type InP buried layer 52 (film thickness: 0.2 μm, doping concentration: 5.0×10¹⁸ cm⁻³). The boundary between the buried layer 50 and the p-type InP first cladding layer 30 is inclined with respect to side faces of the lower part of the mesa 200 so that the width of the p-type InP first cladding layer 30 becomes narrower toward the top of the mesa 200. The buried layer 50 and the p-type InP first cladding layer 30 exposed from the buried layer 50 at the top of the mesa 200 are buried with a p-type InP second cladding layer 31 (thickness: 2.0 μm, doping concentration: 1.0×10¹⁸ cm⁻³). A p-type InP contact layer 80 (thickness: 0.3 μm, doping concentration: 1.0×10¹⁹ cm⁻³) is formed on the upper surface of the p-type InP second cladding layer 31.

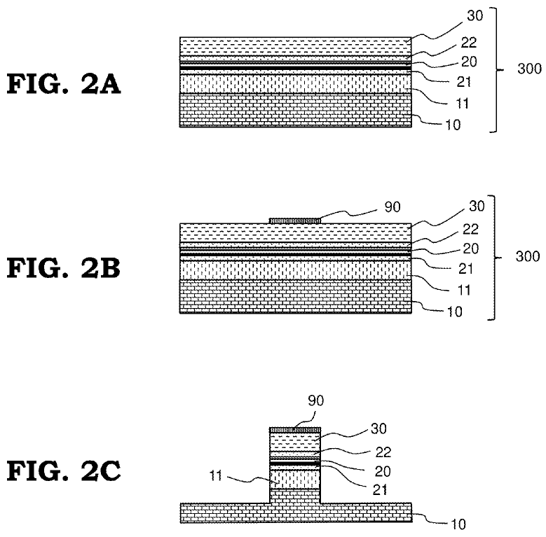

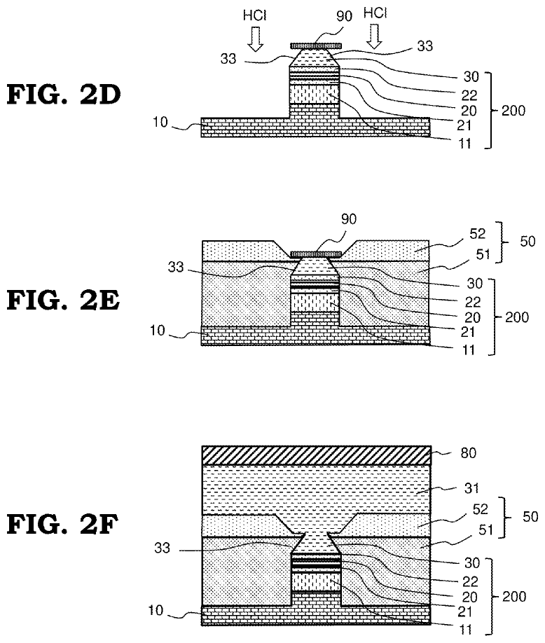

FIG. 2A, FIG. 2B, FIG. 2C, FIG. 2D, FIG. 2E, and FIG. 2F are cross-sectional views showing steps of manufacturing the optical semiconductor device according to Embodiment 1. On the n-type InP substrate 10 with (100) plane, the n-type InP cladding layer 11, the AlGaInAs lower optical confinement layer 21, the undoped AlGaInAs active layer 20, the AlGaInAs upper optical confinement layer 22, and the p-type InP first cladding layer 30 are sequentially grown in a Metal Organic Chemical Vapor Deposition (MOCVD) furnace to form a laminated structure 300 (FIG. 2A). Next, a SiO₂ mask 90 in a stripe shape having a width of 1.5 μm in the <011> direction is formed on the laminated structure 300 by photolithographic technique (FIG. 2B), and the mesa of the laminated body in the stripe shape having a height of 2.0 μm is formed by dry etching (FIG. 2C). Then, by performing a process using HCl gas in the MOCVD furnace, side faces of the p-type InP first cladding layer 30 from the AlGaInAs upper optical confinement layer 22 to an upper portion of the mesa are formed into inclined faces 33 having (111) planes to complete the mesa 200 (FIG. 2D). Next, the Fe-doped InP buried layer 51 and the n-type InP buried layer 52 are sequentially grown as the buried layer 50 on both sides of the mesa 200, and both sides of the mesa 200 are buried with the buried layer 50 with the mask 90 being exposed (FIG. 2E). Next, by removing the SiO₂ mask 90 with hydrofluoric acid and growing the p-type InP second cladding layer 31 and the p-type InP contact layer 80 by MOCVD, an epitaxial structure of the optical semiconductor device according to Embodiment 1 is completed (FIG. 2F).

Since the etching rate with the HCl gas is low for AlGaInAs, the etching shape is from the AlGaInAs upper optical confinement layer 22 as a starting point. In addition, in the etching with the HCl gas in the MOCVD furnace, the (111) plane having a high etching rate in the p-type InP first cladding layer 30 serves as an etching stop plane, so that the (111) plane can be stably formed. Note that the etching gas used to form the inclined faces 33 is not limited to the HCl gas, and may be a halogen-based gas. The upper optical confinement layer 22 provided as the starting point for the inclined faces 33 is not limited to AlGaInAs, but may be a layer containing Ga or Al, such as AlInAs or GaInAs.

After the epitaxial structure shown in FIG. 2F is completed, the epitaxial structure in a portion several μm apart from the stripe of the active layer is etched with HBr down to the InP substrate, an SiO₂ insulating film is formed on the entire surface, the SiO₂ insulating film at a position corresponding to the active layer is opened by dry etching, and metal is formed on the front and back surfaces, thereby completing the basic structure of the semiconductor laser as the optical semiconductor device. Note that the numerical values of the film thickness, the doping concentration, and the like described above are merely examples and are not limited to the exemplified numerical values.

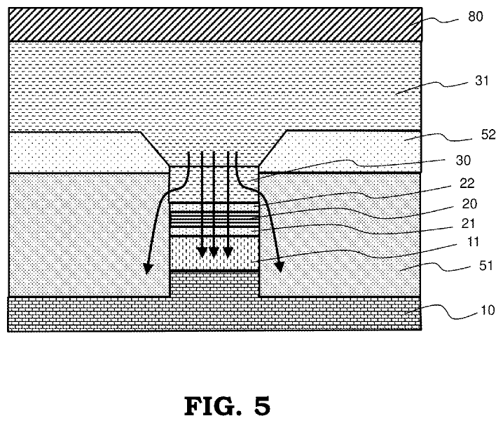

FIG. 5 shows an example of a conventional structure in which a current blocking layer does not constrict the upper portion of the mesa as a comparative example. In the structure of the comparative example, of hole current indicated by the arrows in FIG. 5, the hole current flowing outside the mesa leaks to the Fe-doped InP buried layer 51, and a current component that does not contribute to light emission of the active layer occurs. This is because the Fe-doped InP buried layer 51 has no trapping effect on holes. In contrast, in the structure of Embodiment 1, as shown by the hole current indicated by the arrows in FIG. 1, the hole current is constricted by the n-type InP buried layer 52, so that the component leaking into the Fe-doped InP buried layer 51 can be suppressed. The structure in which the n-type InP buried layer 52 is in contact with the narrowest portion on the inclined faces is the best mode of Embodiment 1.

As another effect of Embodiment 1, there is a viewpoint of dopant diffusion in a portion where the p-type InP first cladding layer 30 and the Fe-doped InP buried layer 51 are in contact with each other. In general, Zn is used as a p-type dopant for InP, and Zn is known as a material whose mutual diffusion with Fe is large. In the interdiffusion of Zn and Fe, it is known that Zn diffuses up to the active concentration of Fe in the Fe-doped InP buried layer 51, and under a normal growth condition, Zn is to be diffused in a concentration from about 5×10¹⁶ cm⁻³ up to 1-5×10¹⁷ cm⁻³. The Fe-doped InP buried layer 51 at the portion where Zn is interdiffused is similar to a layer doped with Zn at a low concentration and has a problem of increasing a hole leak component. When constriction is made by the Fe-doped InP buried layer, the interdiffusion region of Zn and Fe can be narrowed only to constricted regions on the inclined faces, and thus the leakage of the hole current from the p-type InP first cladding layer 30 to the Fe-doped InP buried layer 51 can be further suppressed.

Owing to the effect described above, since the hole current can be efficiently injected into the active layer by suppressing the current leakage component, light emission efficiency of the semiconductor laser as the optical semiconductor device is improved.

Although the structure in which the active layer 20 is sandwiched between the upper optical confinement layer 22 and the lower optical confinement layer 21 is described above, the upper optical confinement layer 22 and the lower optical confinement layer 21 are not necessarily provided. In the case where the upper optical confinement layer 22 and the lower optical confinement layer 21 are not provided, the inclined faces 33 are formed by the etching with the halogen-based gas with the active layer 20 being the starting point.

In Embodiment 1, although the optical semiconductor device using the n-type InP substrate and the manufacturing method for the same have been described, the structure may be made by reversing the conductivity type of each of the semiconductor layers using a p-type InP substrate. In the present application, one of the p-type and n-type conductivity types may be referred to as a first conductivity type and the other as a second conductivity type. That is, the second conductivity type is the conductivity type opposite to the first conductivity type, and if the first conductivity type is p-type, the second conductivity type is n-type, and if the first conductivity type is n-type, the second conductivity type is p-type. In addition, as the semiconductor material, an example mainly using the InP-based material is described, but other semiconductor materials may be used. Therefore, in the present application, without specification of the conductivity type and the material, for example, the member described as the n-type InP substrate may be referred to as a first conductivity type substrate, the member described as the n-type InP cladding layer may be referred to as a first conductivity type cladding layer, the member described as the p-type InP first cladding layer may be referred to as a second conductivity type first cladding layer, and the member described as the p-type InP second cladding layer may be referred to as a second conductivity type second cladding layer.

### Embodiment 2

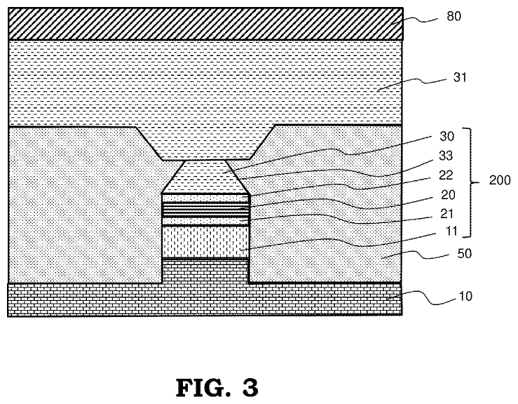

FIG. 3 is a cross-sectional view illustrating a schematic configuration of an optical semiconductor device according to Embodiment 2. The manufacturing method is substantially the same as that of Embodiment 1, but in contrast to Embodiment 1, the buried layer 50 includes only an Fe-doped InP buried layer, and the n-type InP buried layer 52 in Embodiment 1 is not provided.

Even in the structure shown in FIG. 3, since constriction is made by the Fe-doped InP buried layer, mutual diffusion regions of Zn and Fe can be narrowed only to constricted regions on the inclined faces, and thus the leakage of the hole current from the p-type InP first cladding layer 30 to the Fe-doped InP buried layer 50 can be further suppressed. Therefore, as in Embodiment 1, there is an effect of improving light emission efficiency of the semiconductor laser as the optical semiconductor device.

### Embodiment 3

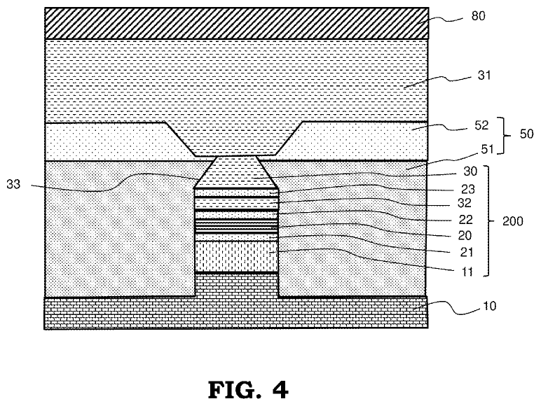

FIG. 4 is a cross-sectional view illustrating a schematic configuration of an optical semiconductor device according to Embodiment 3. The manufacturing method is substantially the same as that of Embodiment 1, but the difference from Embodiment 1 is that an additional p-type InP first cladding layer 32 and an additional AlGaInAs optical confinement layer (additional optical confinement layer) 23 are provided between the upper optical confinement layer 22 and the p-type InP first cladding layer 30, and the additional optical confinement layer 23 serves as the starting point of the inclined faces 33. In this case, the additional optical confinement layer 23 provided as the starting point of the inclined faces 33 is not limited to AlGaInAs as in the case of the upper optical confinement layer 22 in Embodiment 1, but may be a layer containing Ga or Al, such as AlInAs or GaInAs.

In Embodiment 1, when variation in the shape of the buried layer occurs owing to variation in the epitaxial growth temperature or the like and the n-type InP buried layer 52 and the active layer 20 come into contact with each other, electron leakage occurs from the active layer 20 to the n-type InP buried layer 52. In Embodiment 3, the additional p-type InP first cladding layer 32 and the additional optical confinement layer 23 are further added on the upper optical confinement layer 22 to make the starting point of the inclined faces 33 at the additional optical confinement layer 23. With this structure, the starting point of the inclined faces 33 can be kept away from the active layer 20, and a contact between the n-type InP buried layer 52 and the active layer 20 can be avoided. Therefore, both risks of the hole leakage and the electron leakage can be suppressed, and light emission efficiency of the semiconductor laser as the optical semiconductor device can be improved more stably.

Although various exemplary embodiments and examples are described in the present application, various features, aspects, and functions described in one or more embodiments are not inherent in a particular embodiment, and can be applicable alone or in their various combinations to each embodiment. Accordingly, countless variations that are not illustrated are envisaged within the scope of the art disclosed herein. For example, the case where at least one component is modified, added or omitted, and the case where at least one component is extracted and combined with a component in another embodiment are included.

### DESCRIPTION OF REFERENCE NUMERALS AND SIGNS

10 n-type InP substrate (first conductivity type substrate), n-type InP cladding layer (first conductivity type cladding layer), 20 active layer, 21 lower optical confinement layer, 22 upper optical confinement layer, 23 additional optical confinement layer, 30 p-type InP first cladding layer (second conductivity type first cladding layer), 31 p-type InP second cladding layer (second conductivity type second cladding layer), 32 additional p-type InP first cladding layer (additional second conductivity type first cladding layer), 33 inclined face, 50 buried layer, 51 Fe-doped InP buried layer, 52 n-type InP buried layer, 90 mask, 200 mesa, 300 laminated structure

1. An optical semiconductor device comprising:
a mesa in which a first conductivity type cladding layer having a first conductivity type, an active layer, and a second conductivity type first cladding layer having a second conductivity type being a conductivity type opposite to the first conductivity type are sequentially laminated on a surface of a first conductivity type substrate having the first conductivity type;
a buried layer that buries both sides of the mesa with a top of the mesa being exposed; and
a second conductivity type second cladding layer having the second conductivity type that buries the buried layer and the top of the mesa exposed from the buried layer, wherein
the buried layer includes a layer doped with a semi-insulating material and a first conductivity type layer at a position higher than the layer doped with the semi-insulating material;
a boundary between the second conductivity type first cladding layer and the buried layer is inclined so that a width of the second conductivity type first cladding layer becomes narrower toward the top of the mesa; and
the layer doped with the semi-insulating material and the first conductivity type layer are in contact with inclined faces of the second conductivity type first cladding layer.

2. (canceled)

3. The optical semiconductor device according to claim 1, wherein an upper optical confinement layer and a lower optical confinement layer are provided so as to sandwich the active layer.

4. The optical semiconductor device according to claim 3, further comprising an additional second conductivity type first cladding layer and an additional optical confinement layer between the upper optical confinement layer and the second conductivity type first cladding layer.

5. A manufacturing method for an optical semiconductor device comprising the steps of:
forming a laminated structure by sequentially laminating a first conductivity type cladding layer having a first conductivity type, an active layer, and a second conductivity type first cladding layer having a second conductivity type being a conductivity type opposite to the first conductivity type on the surface of a first conductivity type substrate having a first conductivity type in an MOCVD furnace;
forming a mesa by forming a mask having a predetermined width on a surface of the laminated structure and by etching both sides of the laminated structure to a position closer to the first conductivity type substrate than the active layer by dry etching;
forming side faces of the second conductivity type first cladding layer to be inclined faces by etching the formed mesa with a halogen-based gas flowing into the MOCVD furnace while the mask is left;
burying both sides of the mesa formed to be the inclined faces in the side faces of the second conductivity type first cladding layer with a buried layer including a layer doped with a semi-insulating material and a first conductivity type layer at a position higher than the layer doped with the semi-insulating material so that the layer doped with the semi-insulating material and the first conductivity type layer are in contact with the inclined faces; and
forming a second conductivity type second cladding layer to cover the buried layer and the second conductivity type first cladding layer that is exposed at a top of the mesa after removing the mask.

6. The manufacturing method for the optical semiconductor device according to claim 5, wherein, in the step of forming the laminated structure, a lower optical confinement layer is laminated between the active layer and the first conductivity type cladding layer, and an upper optical confinement layer is laminated between the active layer and the second conductivity type first cladding layer.

7. The manufacturing method for the optical semiconductor device according to claim 6, wherein the upper optical confinement layer is a layer containing Ga or Al.

8. The manufacturing method for the optical semiconductor device according to claim 6, wherein, in the step of forming the laminated structure, an additional second conductivity type first cladding layer and an additional optical confinement layer are laminated between the upper optical confinement layer and the second conductivity type first cladding layer.

9. The manufacturing method for the optical semiconductor device according to claim 8, wherein the additional optical confinement layer is a layer containing Ga or Al.
